(19) United States
(12) Patent Application Publication
(10) Pub. No.: US 2026/0182060 A1
(43) Pub. Date: Jun. 25, 2026

(54) IMAGING ELEMENT

(71) Applicant: SONY SEMICONDUCTOR SOLUTIONS CORPORATION, Kanagawa (JP)

(72) Inventor: Yosuke MOGAMI, Kanagawa (JP)

(73) Assignee: SONY SEMICONDUCTOR SOLUTIONS CORPORATION, Kanagawa (JP)

(21) Appl. No.: 19/127,082

(22) PCT Filed: Oct. 18, 2023
(86) PCT No.: PCT/JP2023/037625

§ 371 Date: May 2, 2025

(30) Foreign Application Priority Data
Nov. 18, 2022 (JP) 2022-184875

(51) Int. Cl. H10F 39/00

(52) U.S. Cl. CPC H10F 39/8063; H10F 39/8053

(57) ABSTRACT

An imaging device is provided. The imaging device includes: a plurality of unit pixels arranged two-dimensionally; and a light-focusing layer that focuses light toward the plurality of unit pixels. Each of the plurality of unit pixels includes a first pixel section having a first area and a second pixel section having a second area smaller than the first area. The light-focusing layer includes a material having a first refractive index, and a plurality of structures provided in the material. Each of the plurality of structures has a second refractive index higher than the first refractive index, and has a width smaller than a wavelength of light of an associated color filter. The plurality of structures are disposed corresponding to the first pixel section and the second pixel section.

### CROSS REFERENCE TO RELATED APPLICATIONS

This application claims the benefit of Japanese Priority Patent Application JP2022-184875 filed Nov. 18, 2022, the entire contents of which are incorporated herein by reference.

### TECHNICAL FIELD

The present disclosure relates to an imaging element.

### BACKGROUND ART

There is an imaging device in which a lens and fine structures that focus light are disposed on a unit pixel (see PTL 1). Meanwhile, as a method of enlarging a dynamic range, there is a method of dividing a unit pixel into a plurality of pixel sections having different areas.

CITATION LIST

### Patent Literature

[PTL 1] Japanese Unexamined Patent Application Publication No. 2008-66702

### SUMMARY

### Technical Problem

In a case where a lens is used to focus light in a pixel structure in which a unit pixel is divided into a plurality of pixel sections, an area ratio of the plurality of pixel sections is limited by a size of the lens. For this reason, expansion of a realizable dynamic range is limited.

It is desirable to provide an imaging device that makes it possible to expand a dynamic range.

### Solution to Problem

An imaging device according to an embodiment of the present disclosure includes: a plurality of unit pixels arranged two-dimensionally; and a light-focusing layer that focuses light toward the plurality of unit pixels. Each of the plurality of unit pixels includes a first pixel section having a first area and a second pixel section having a second area smaller than the first area. The light-focusing layer includes a material having a first refractive index, and a plurality of structures provided in the material. Each of the plurality of structures has a second refractive index higher than the first refractive index, and has a width smaller than a wavelength of light of an associated color filter. The plurality of structures are disposed corresponding to the first pixel section and the second pixel section.

### BRIEF DESCRIPTION OF DRAWINGS

FIG. 1 is a plan view schematically illustrating a first configuration example of an imaging device according to a comparative example.

FIG. 2 is a plan view schematically illustrating a second configuration example of an imaging device according to a comparative example.

FIG. 3 is a plan view schematically illustrating a third configuration example of an imaging device according to a comparative example.

FIG. 4 is an explanatory diagram illustrating a first configuration example of a metasurface.

FIG. 5 is an explanatory diagram illustrating a second configuration example of a metasurface.

FIG. 6 is a plan view schematically illustrating a first configuration example of an imaging device according to an embodiment of the present disclosure.

FIG. 7 is a cross-sectional view schematically illustrating the first configuration example of the imaging device according to an embodiment.

FIG. 8 is a plan view schematically illustrating a second configuration example of an imaging device according to an embodiment.

FIG. 9 is a plan view schematically illustrating a third configuration example of an imaging device according to an embodiment.

FIG. 10 is a plan view schematically illustrating a fourth configuration example of an imaging device according to an embodiment.

FIG. 11 is a cross-sectional view schematically illustrating the fourth configuration example of the imaging device according to an embodiment.

FIG. 12 is a plan view schematically illustrating a fifth configuration example of an imaging device according to an embodiment.

FIG. 13 is a cross-sectional view schematically illustrating the fifth schematic configuration example of the imaging device according to an embodiment.

FIG. 14 is a block diagram depicting an example of schematic configuration of a vehicle control system.

FIG. 15 is a diagram depicting an example of installation positions of an outside-vehicle information detecting section and an imaging section.

### DESCRIPTION OF EMBODIMENTS

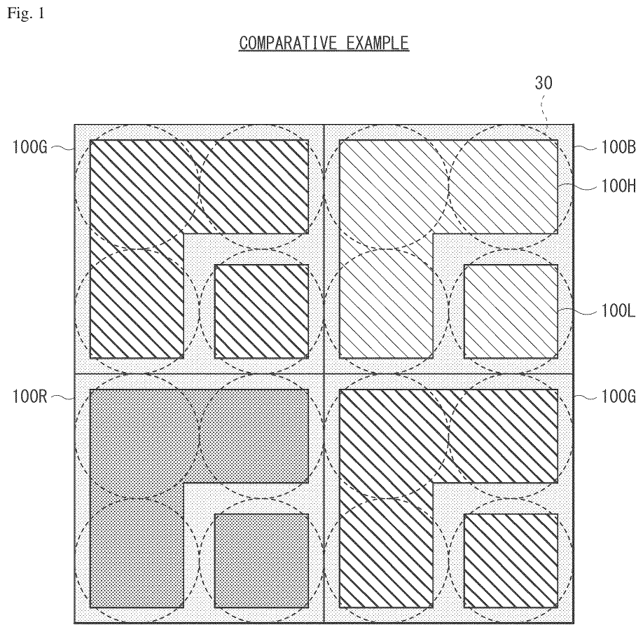

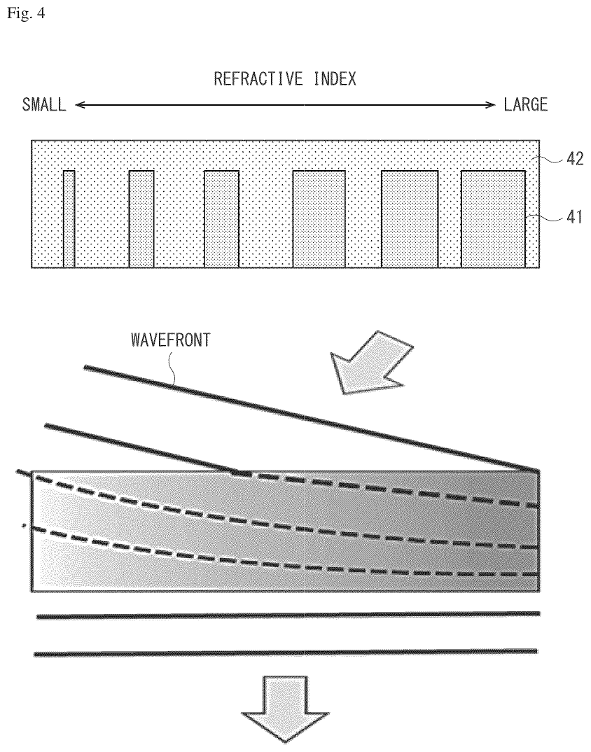

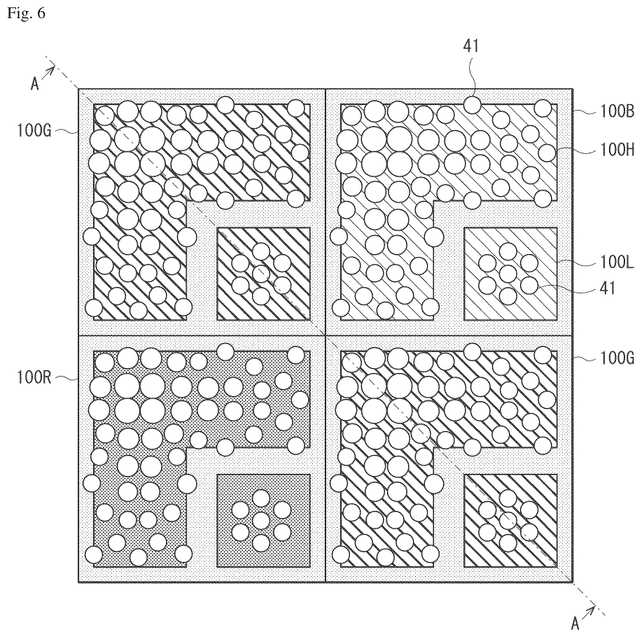

Hereinafter, description is given in detail of embodiments of the present disclosure with reference to the drawings. It is to be noted that the description is given in the following order.
0. Comparative Examples (FIGS. 1 to 3)
1. Embodiment
1.1 Overview (FIG. 4 and. 5)
1.2 Configuration Examples (FIGS. 6 to 13)
1.3

Effects
2.

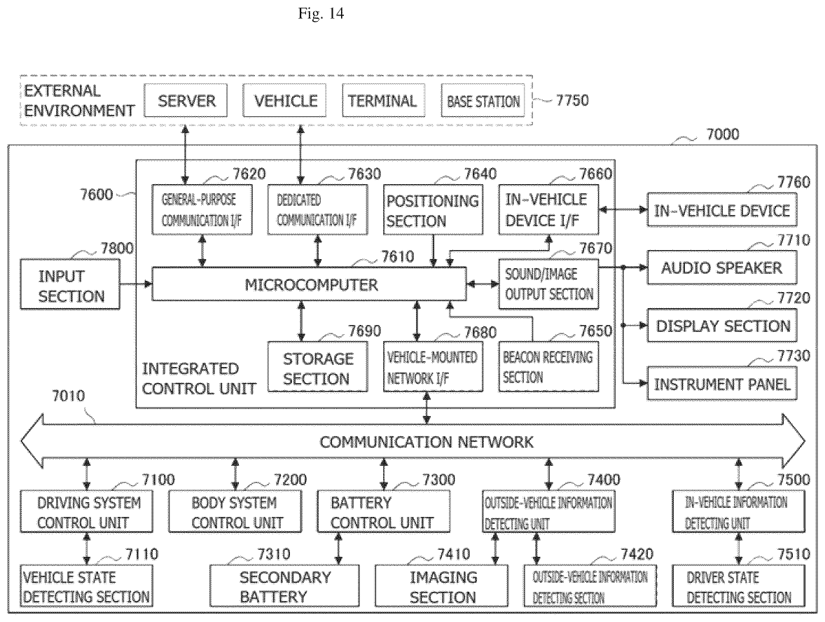

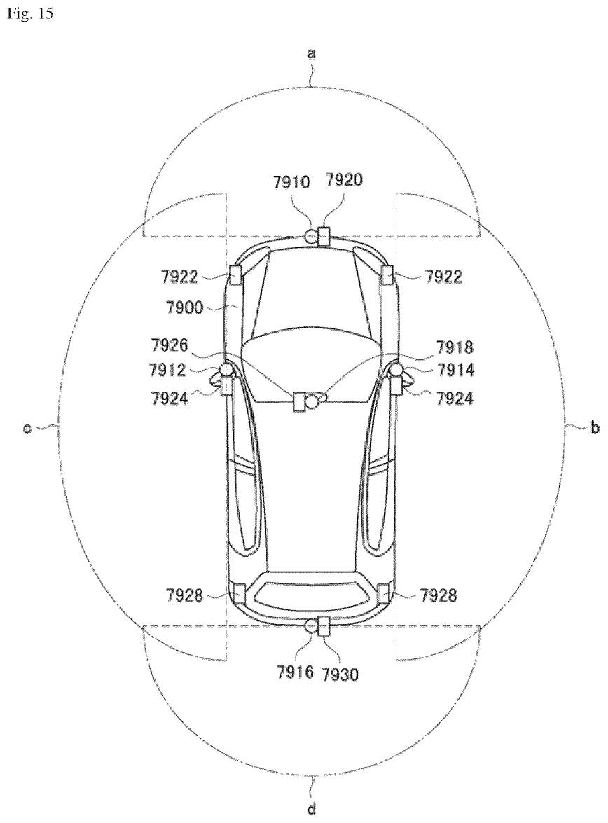

Practical Application Examples (FIGS. 14 and 15)
3. Other Embodiments

### 0. Comparative Examples

FIG. 1 is a plan view schematically illustrating a first configuration example of an imaging device according to a comparative example.

The imaging device according to the comparative example includes a plurality of unit pixels arranged two-dimensionally, and a light-focusing layer that focuses light toward the plurality of unit pixels.

FIG. 1 illustrates a configuration example in which a R (red) pixel 100R, G (green) pixels 100G, and a B (blue) pixel 100B are arranged as the plurality of unit pixels.

Each of the plurality of unit pixels has a first pixel section (a large area pixel 100H) having a first area and a second pixel section (a smaller area pixel 100L) having a second area smaller than the first area. The large pixel 100H and the smaller area pixel 100L are separated from each other. An area of the second pixel section 100L is smaller than an area of the first pixel section 100H. A planar shape of the first pixel section 100H is an L-shape, and a planar shape of the second pixel section 100L is rectangular (e.g., square).

The imaging device according to the comparative example includes a lens array in which microlenses 30 are two-dimensionally arranged as the light-focusing layer. In the imaging device according to the comparative example, as illustrated in FIG. 1, the L-shaped (or approximately L-shaped) first pixel section and the rectangular second pixel section are set as a unit pixel, and the microlenses 30 having an equal size are provided on an entire surface to focus incident light on each of the pixel sections. In this way, an area ratio is set between the first pixel section and the second pixel section, thus making it possible to improve a dynamic range while avoiding generation of a difference in light-focusing characteristics due to a difference in shapes of the lenses.

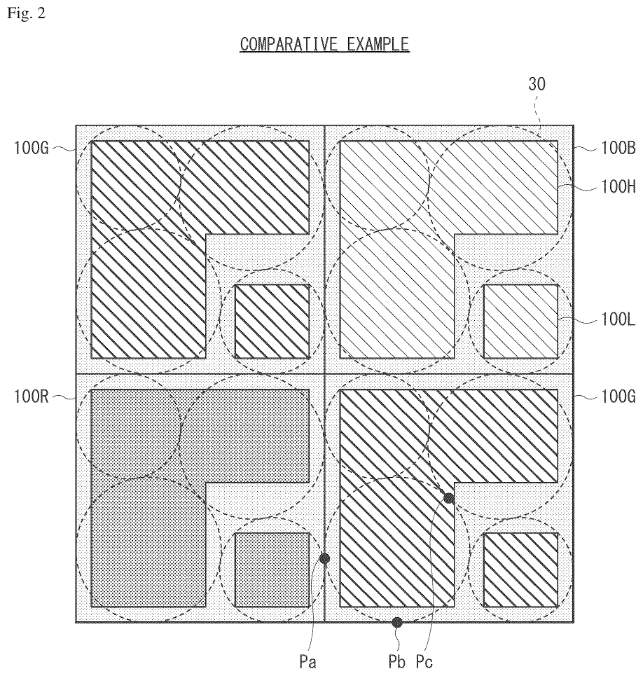

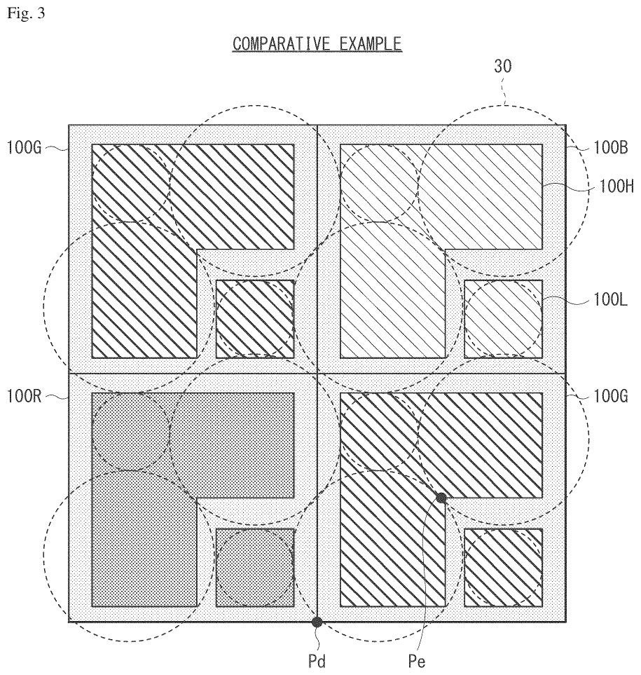

FIG. 2 is a plan view schematically illustrating a second configuration example of an imaging device according to a comparative example. FIG. 3 is a plan view schematically illustrating a third configuration example of an imaging device according to a comparative example.

In a pixel structure illustrated in FIG. 1, the area ratio is determined by an occupied area ratio of the microlenses 30. In the first configuration example of FIG. 1, the area ratio is fixed at about three times. In order to further increase the dynamic range, a larger area ratio is required. As a method to set an area ratio, there is a method of resizing the microlenses 30 as in the second configuration example illustrated in FIG. 2. However, in the second configuration example illustrated in FIG. 2, a size of the microlens 30 is maximized in a case where illustrated points Pa and Pb are at a boundary between the unit pixels and a point Pc is at a center of the unit pixel, and there is a limit to a realizable area ratio. In contrast, as in the third configuration example illustrated in FIG. 3, by providing a portion of the microlens 30 to cross a boundary between unit pixels, it is possible to increase the size of the microlens 30.

However, even in the case of the third configuration example, the size of the microlens 30 is maximized in a case where an illustrated point Pd is located at four corners of the unit pixels and a point Pe is located at a center of a unit pixel. For this reason, there is a limit to the realizable area ratio even in the case of the third configuration example. For these reasons, in the case where the microlenses 30 are used as the light-focusing layer, there is a limit to a realizable dynamic range.

### 1. Embodiment

### 1.1 Overview

An imaging device according to an embodiment includes a plurality of unit pixels arranged two-dimensionally, and a light-focusing layer that focuses light toward the plurality of unit pixels. Each of the plurality of unit pixels includes a first pixel section having a first area and a second pixel section having a second area smaller than the first area. As used herein pixel may refer to a pixel unit comprising one or more pixel sections. Additionally, pixel may refer to a pixel array comprising multiple pixel units. Pixel may also refer to each pixel section (e.g., first and second pixel sections).

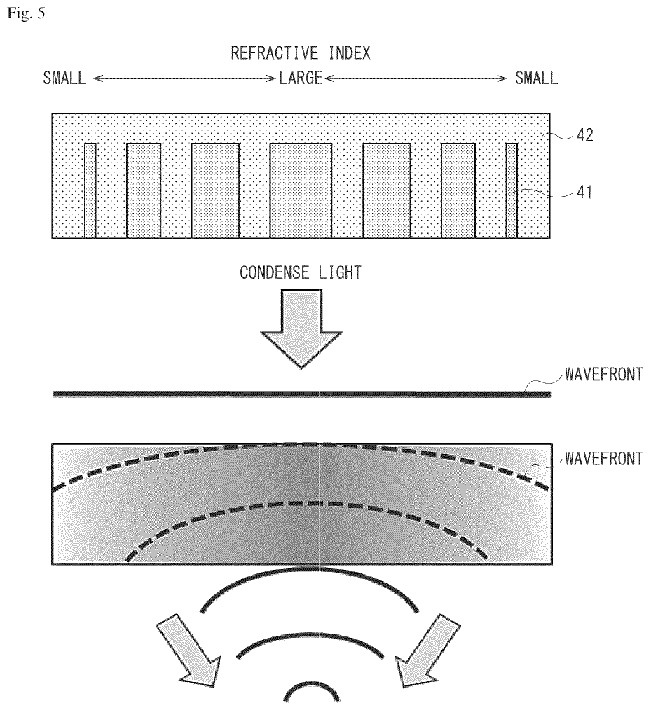

In the imaging device according to the embodiment, a metasurface is used as the light-focusing layer. FIG. 4 is an explanatory diagram illustrating a first configuration example of a metasurface. FIG. 5 is an explanatory diagram illustrating a second configuration example of a metasurface.

A metasurface causes light to deflect by two-dimensionally disposing fine structures smaller than a wavelength of light in a material and creating a gradient in the effective refractive index by the material and the fine structures. For example, as illustrated in FIGS. 4 and 5, the configuration includes a material 42 including a low refractive index material having a first refractive index, and a plurality of structures 41 provided in the material 42, each including a high refractive index material having a second refractive index higher than the first refractive index. Each of the plurality of structures 41 has a width smaller than the wavelength of light of an associated color filter. In the first configuration example of FIG. 4, the width of the plurality of structures 41 increases from a left side toward a right side, and a disposition interval decreases from the left side toward the right side, to allow the effective refractive index distribution to increase from the left side toward the right side. In the second configuration example of FIG. 5, the width of the plurality of structures 41 decreases from a center toward a left side and a right side, and a disposition interval increases from the center toward the left side and the right side, to allow the effective refractive index distribution to decrease from the center toward the left side and the right side. Incident light is deflected in accordance with the effective refractive index distribution.

In the imaging device according to the embodiment, the plurality of structures 41 are two-dimensionally disposed corresponding to the first pixel section and the second pixel section. In embodiments, the plurality of structures 41 may vary in fill factor, height, diameter, distance to neighboring structures, etc. In embodiments, the fill factor, height, diameter, distance to neighboring structures, etc. may depend on a color of an associated color filter. By using the metasurface as the light-focusing layer, it is possible to set the area ratio without being influenced by an aperture area of the pixel. As a result, it is possible to expand the dynamic range. Additionally, with use of the metasurface the on-chip lens (OCL) may be omitted from the light receiving surface of the substrate.

### 1.2 Configuration Example

Hereinafter, description is given of a specific configuration example of the imaging device according to the embodiment.

### First Configuration Example

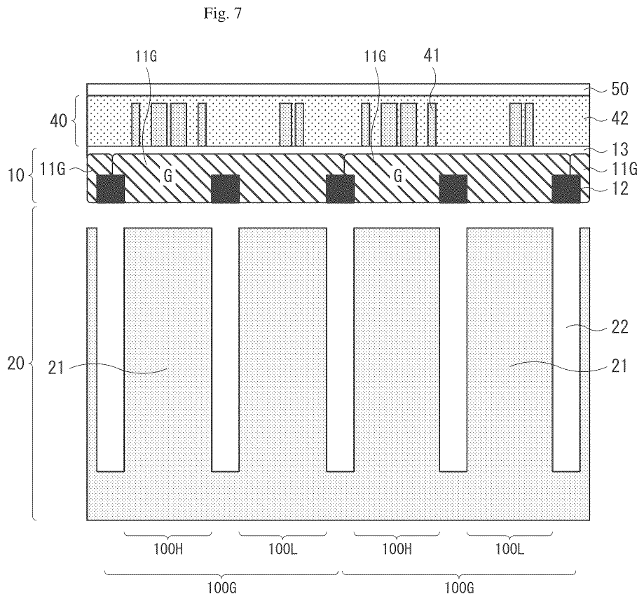

FIG. 6 is a plan view schematically illustrating a first configuration example of the imaging device according to the embodiment of the present disclosure. FIG. 7 is a cross-sectional view schematically illustrating the first configuration example of the imaging device according to the embodiment. FIG. 6 is a plan view of a pixel structure as viewed from a light-incidence direction. For simplicity, only four unit pixels are illustrated as a plurality of unit pixels. FIG. 7 illustrates a cross-sectional structure corresponding to a portion along a line A-A in FIG. 6.

FIG. 6 illustrates a configuration example in which the R pixel 100R, the G pixels 100G, and the B pixel 100B are arranged as the plurality of unit pixels. Each of the plurality of unit pixels has a first pixel section (the large area pixel section 100H) having a first area and a second pixel section (the smaller area pixel section 100L) having a second area lower than the first area. The first pixel section 100H and the second pixel section 100L are pixel-separated from each other. An area of the second pixel section 100L is smaller than an area of the first pixel section 100H. A planar shape of the first pixel section 100H is an L-shape, and a planar shape of the section pixel section 100L is rectangular (e.g., square).

As illustrated in FIG. 7, the imaging device according to the first configuration example includes a light-receiving layer 20, a filter layer 10 stacked on the light-receiving layer 20, and a light-focusing layer 40 stacked on the filter layer 10.

The light-receiving layer 20 includes, for example, a semiconductor substrate, and includes a plurality of light-receiving elements 21 arranged two-dimensionally to correspond to the first pixel section 100H and the second pixel section 100L of each of the unit pixels. The light-receiving element 21 includes, for example, a PD (photodiode). The light-receiving element 21 outputs a pixel signal corresponding to incident light. The plurality of light-receiving elements 21 are pixel-separated by pixel separating sections 22.

The filter layer 10 includes a plurality of color filters arranged two-dimensionally corresponding to the plurality of unit pixels and differ in color from each other. The plurality of color filters includes a Red filter 11R, a Green filter 11G, and a Blue filter 11B. It is to be noted that only the Green filter 11G is illustrated in FIG. 7. Light-blocking films 12 are provided in the filter layer 10 at positions corresponding to a boundary part between the plurality of unit pixels and a boundary part between the first pixel section 100H and the second pixel section 100L. A planarization film (spacer film) 13 is provided between the plurality of color filters and the light-focusing layer 40.

The light-focusing layer 40 includes a metasurface described above, and includes the material 42 including a low refractive index material and the plurality of structures 41 including a high refractive index material. FIG. 6 illustrates a configuration in a case where the plurality of structures 41 are cylindrical, although it is understood that other configurations are possible. The cylindrical structures 41 including the high refractive index material are disposed to allow a high occupancy ratio in a direction in which light is to be focused, and other portions are filled with the material 42 including the low refractive index material to form a metasurface as the light-focusing layer 40. A diameter of each cylinder of the plurality of structures 41 and an interval between the cylinders are adjusted to change the occupancy ratio (e.g., fill factor) on a surface. In addition, a height of the cylinder is also adjusted corresponding to an amount of deflection of light required to preferentially focus light on the first pixel section 100H.

Further, it is also possible to adjust the disposition of the cylinders appropriate for every color filter. An antireflection film 50 may be disposed above the light-focusing layer 40 that covers the cylindrical high refractive index material by using an oxide film, or the like.

It is to be noted that, in the imaging device according to the first configuration example, the number and arrangement of the plurality of structures 41 and the plurality of unit pixels in the light-focusing layer 40 are not limited to the illustrated example, and other configurations may be adopted. In addition, the type and number of colors of the color filters are not limited to the illustrated example, and other configurations may be adopted.

### Second Configuration Example

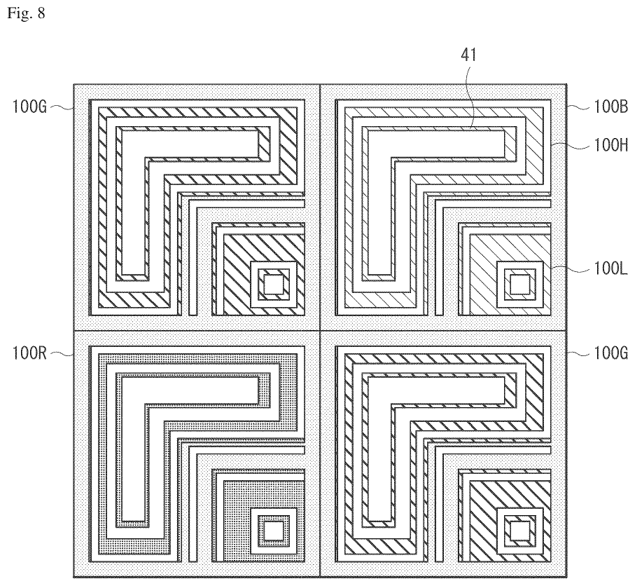

FIG. 8 is a plan view schematically illustrating a second configuration example of the imaging device according to the embodiment. FIG. 8 is a plan view of a pixel structure as viewed from a light-incidence direction. For simplicity, only four unit pixels are illustrated as a plurality of unit pixels.

Similar to the imaging device according to the foregoing first configuration example, the imaging device according to the second configuration example includes the light-receiving layer 20, the filter layer 10 stacked on the light-receiving layer 20, and the light-focusing layer 40 stacked on the filter layer 10.

The imaging device according to the second configuration example differs from the imaging device according to the foregoing first configuration example in shapes and disposition of the plurality of structures 41 in the light-focusing layer 40.

In the imaging device according to the second configuration example, a planar shape of the plurality of structures 41 is configured to include a linear pattern. FIG. 8 illustrates a configuration example including a ring-shaped pattern and an L-shaped pattern as the linear pattern.

In the imaging device according to the second configuration example, the plurality of structures 41 that include a linear pattern including a high refractive index material are disposed to allow a high occupancy ratio in a direction in which light is to be focused, and other portions are filled with the material 42 including a low refractive index material to form a metasurface as the light-focusing layer 40. In a planar position corresponding to the first pixel section 100H and the second pixel section 100L, the linear pattern may be a closed ring shape, or may be formed by a linear pattern having a width larger than the ring-shaped pattern at a center part of an aperture of the pixel or between pixels. A diameter and an interval of the plurality of structures 41 including the linear pattern are adjusted to change the occupancy ratio on a surface. In addition, a height of the plurality of structures 41 is also adjusted corresponding to an amount of deflection of light required to preferentially focus light on the first pixel section 100H. Further, it is also possible to adjust the disposition of a linear pattern appropriate for every color filter. The antireflection film 50 may be formed on the low refractive index material that covers the plurality of structures 41 by using an oxide film, or the like.

It is to be noted that, in the imaging device according to the second configuration example, the number and arrangement of the plurality of structures 41 and the plurality of unit pixels in the light-focusing layer 40 are not limited to the illustrated example, and other configurations may be adopted.

Other configurations may be substantially similar to those in the imaging device according to the foregoing first configuration example.

### Third Configuration Example

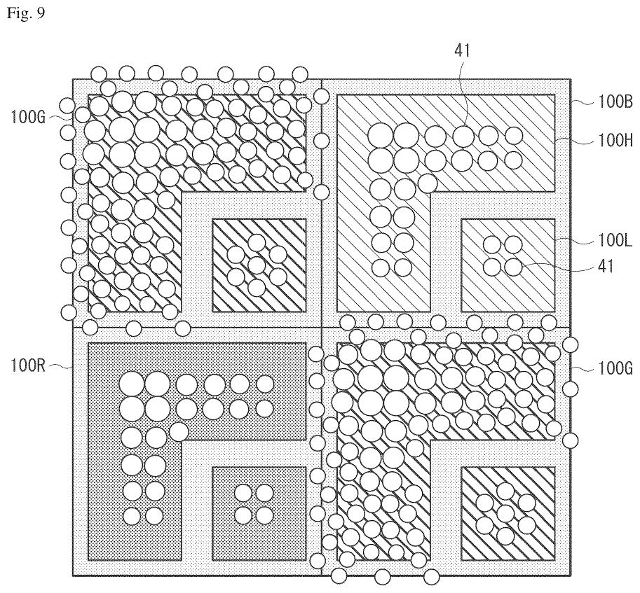

FIG. 9 is a plan view schematically illustrating a third configuration example of the imaging device according to the embodiment. FIG. 9 is a plan view of a pixel structure as viewed from a light-incidence direction. For simplicity, only four unit pixels are illustrated as a plurality of unit pixels.

As similar to the imaging device according to the first configuration example, the imaging device according to the third configuration example includes the light-receiving layer 20, the filter layer 10 stacked on the light-receiving layer 20, and the light-focusing layer 40 stacked on the filter layer 10.

The imaging device according to the third configuration example differs from the imaging device according to the foregoing first configuration example in a disposition of the plurality of structures 41 in the light-focusing layer 40.

In the imaging device according to the third configuration example, the disposition of the plurality of structures 41 is a disposition corresponding to a color of color filters. FIG. 9 illustrates an example in which, to make the Green pixels 100G have a higher sensitivity, the disposition of the plurality of structures 41 is adjusted to cause a portion of light incident on the Red pixel 100R or the Blue pixel 100B to focus on sides of the Green pixels 100G, as compared with the foregoing first configuration example. In order for more light to be focused on the sides of the Green pixels 100G, more of the plurality of structures 41 (e.g., fill factor) are disposed at positions corresponding to the Green pixels 100G, as compared with the Red pixel 100R and the Blue pixel 100B. The antireflection film 50 may be formed on the low refractive index material that covers the high refractive index material by using an oxide film, or the like.

It is to be noted that, in the imaging device according to the third configuration example, the number and arrangement of the plurality of structures 41 and the plurality of unit pixels in the light-focusing layer 40 are not limited to the illustrated example, and other configurations may be adopted.

Other configurations may be substantially similar to those in the imaging device according to the foregoing first configuration example.

### Fourth Configuration Example

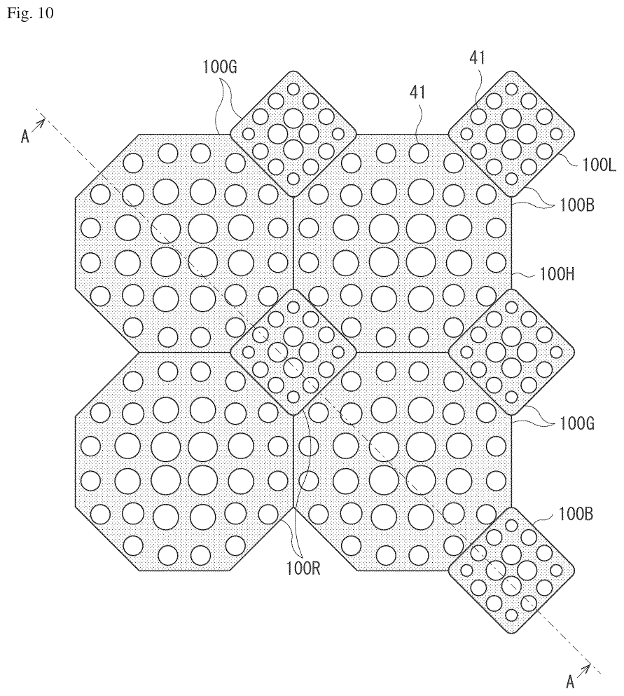

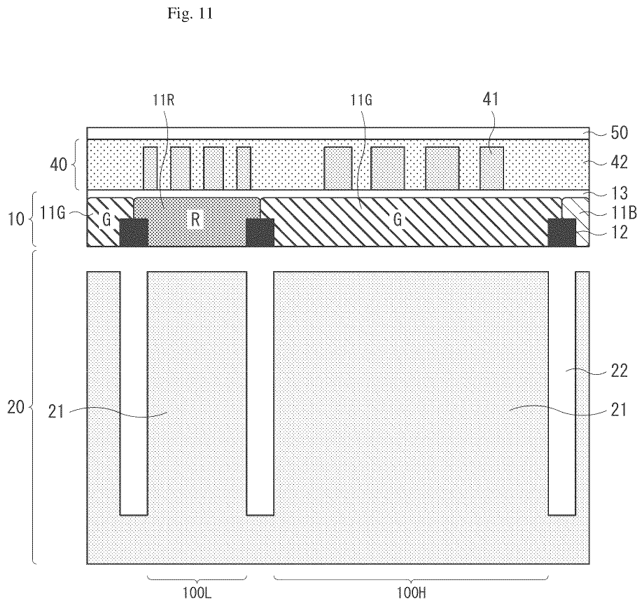

FIG. 10 is a plan view schematically illustrating a fourth configuration example of the imaging device according to the embodiment. FIG. 11 is a cross-sectional view schematically illustrating the fourth configuration example of the imaging device according to the embodiment. FIG. 10 is a plan view of a pixel structure as viewed from a light-incidence direction. For simplicity, only four unit pixels are illustrated as a plurality of unit pixels. FIG. 11 illustrates a cross-sectional structure corresponding to a portion along a line A-A in FIG. 10.

As similar to the imaging device according to the foregoing first configuration example, the imaging device according to the fourth configuration example includes the light-receiving layer 20, the filter layer 10 stacked on the light-receiving layer 20, and the light-focusing layer 40 stacked on the filter layer 10.

The imaging device according to the fourth configuration example differs from the imaging device according to the foregoing first configuration example in the shapes of the plurality of unit pixels. In the fourth configuration example, in each of the unit pixels, a planar shape of the first pixel section 100H is octagonal and a planar shape of the second pixel section 100L is rectangular (e.g., square). The first pixel section 100H and the second pixel section 100L are arranged to allow one side of the octagonal first pixel section 100H to be adjacent to one side of the second pixel section 100L.

FIG. 10 illustrates a configuration in a case where the plurality of structures 41 in the light-focusing layer 40 is cylindrical, as similar to the imaging device according to the foregoing first configuration example. The cylindrical structures 41 including a high refractive index material are disposed to allow a high occupancy ratio in a direction in which light is to be focused, and other portions are filled with the material 42 including a low refractive index material to form a metasurface as the light-focusing layer 40. A diameter of each cylinder of the plurality of structures 41 and an interval between the cylinders are adjusted to change the occupancy ratio on a surface. In addition, a height of the cylinder is also adjusted corresponding to an amount of deflection of light required to preferentially focus light on the first pixel section 100H. Further, it is also possible to adjust a disposition of the cylinders appropriate for every color filter. The antireflection film 50 may be formed on the low refractive index material that covers the cylindrical high refractive index material by using an oxide film, or the like.

In a case where the microlens 30 is used as the light-focusing layer 40, when the first pixel section 100H has an octagonal shape, reducing a diameter of the microlens 30 to be disposed on the second pixel section 100L makes it possible to increase an area ratio. However, in a case where the microlens 30 is used, the height of the lenses changes between the first pixel section 100H and the second pixel section 100L. This results in a difference in oblique incident characteristic and changes in area ratio by the f-number. Meanwhile, in a case where a metasurface is used as the light-focusing layer 40, it is possible to design the light-focusing layer 40 to have the same height between the first pixel section 100H and the second pixel section 100L. This makes it possible to reduce differences in light-focusing characteristics other than area.

It is to be noted that, in the imaging device according to the fourth configuration example, the number and arrangement of the plurality of structures 41 and the plurality of unit pixels in the light-focusing layer 40 are not limited to the illustrated example, and other configurations may be adopted. In addition, the type and number of colors of the color filters are not limited to the illustrated example, and other configurations may be adopted.

Other configurations may be substantially similar to the imaging device according to the foregoing first configuration example.

### Fifth Configuration Example

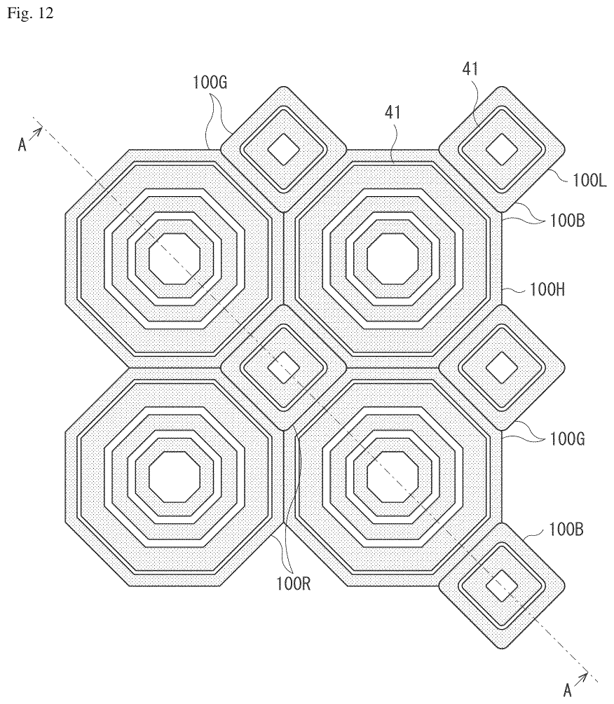

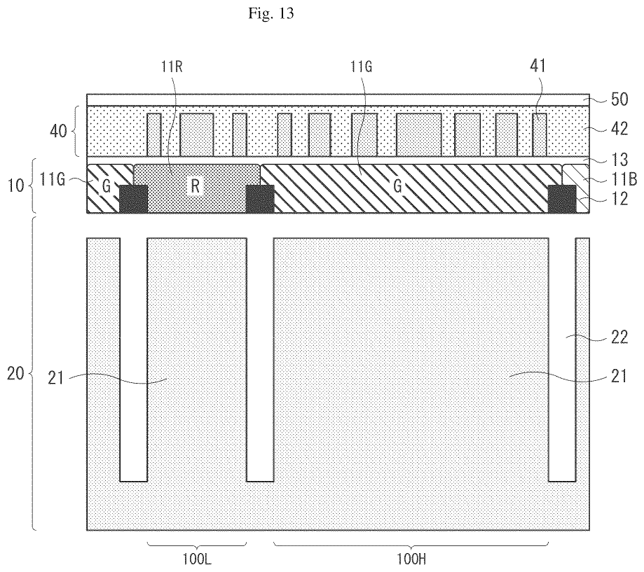

FIG. 12 is a plan view schematically illustrating a fifth configuration example of the imaging device according to the embodiment. FIG. 13 is a cross-sectional view schematically illustrating the fifth configuration example of the imaging device according to the embodiment. FIG. 12 is a plan view of a pixel structure as viewed from a light-incidence direction. For simplicity, only four unit pixels are illustrated as a plurality of unit pixels. FIG. 13 illustrates a cross-sectional structure corresponding to a portion along a line A-A in FIG. 12.

As similar to the imaging device according to the foregoing fourth configuration example, the imaging device according to the fifth configuration example includes the light-receiving layer 20, the filter layer 10 stacked on the light-receiving layer 20, and the light-focusing layer 40 stacked on the filter layer 10.

In the imaging device according to the fifth configuration example, as similar to the imaging device according to the fourth configuration example, in each of the unit pixels, a planar shape of the first pixel section 100H is octagonal and a planar shape of the second pixel section 100L is rectangular (e.g., square). However, the imaging device according to the fifth configuration example differs from the imaging device according to the foregoing fourth configuration example in the shapes and a disposition of the plurality of structures 41 in the light-focusing layer 40.

In the imaging device according to the fifth configuration example, a planar shape of the plurality of structures 41 is configured to include a linear pattern. FIG. 12 illustrates a configuration example including a ring-shaped pattern as the linear pattern.

In the imaging device according to the fifth configuration example, the structures 41 that include the linear pattern including a high refractive index material are disposed to allow a high occupancy ratio in a direction in which light is to be focused, and other portions are filled with the material 42 including a low refractive index material to form a metasurface as the light-focusing layer 40. In a planar position corresponding to the first pixel section 100H and the second pixel section 100L, the linear pattern may be a closed ring shape, or may be formed by the linear pattern having a width larger than the ring-shaped pattern at a center part of an aperture of the pixel or between the pixels. Further, a partially cylindrical structure may be formed as the plurality of structures 41. A diameter and an interval of the plurality of structures 41 including the linear pattern are adjusted to change the occupancy ratio on a surface. In addition, a height of the plurality of structures 41 is also adjusted corresponding to an amount of deflection of light required to preferentially focus light on the first pixel section 100H. Further, it is also possible to adjust the disposition of the linear pattern appropriate for every color filter. The antireflection film 50 may be formed on the low refractive index material that covers the plurality of structures 41 by using an oxide film, or the like.

Other configurations may be substantially similar to the imaging device according to the foregoing fourth configuration example.

### 1.3 Effects

As described above, according to the imaging device of the embodiment, the plurality of structures 41 having a width smaller than the wavelength of light of an associated color filter are disposed corresponding to the first pixel section (large area pixel 100H) and the second pixel section (smaller area pixel 100L) in each of the plurality of unit pixels. As a result, it is possible to expand the dynamic range.

Further, according to the imaging device of the embodiment, by using the metasurface as the light-focusing layer 40, it is possible to increase the sensitivity ratio regardless of the arrangement or the shape of the first pixel section 100H and the second pixel section 100L. It is possible to focus preferentially on the first pixel section 100H, and that makes it possible to increase the quantum-efficiency. Meanwhile, because it is possible to reduce the amount of light entering the second pixel section 100L, the amount of light saturation increases. These effects are combined to enable expansion of the dynamic range.

Further, according to the imaging device of the embodiment, unlike the case where the microlens 30 is used as the light-focusing layer 40, it is possible to make the thickness of the light-focusing layer 40 uniform. It is possible to reduce differences in light-focusing characteristics (such as light dispersion and oblique incidence) other than area that occurs between the first pixel section 100H and the second pixel section 100L. Further, according to the imaging device of the embodiment, it is possible to focus light at a position close to a transfer gate for the pixel signal. As a result, it is possible to shorten a transfer path and to reduce the possibility of loss due to recombination of the photoelectrically converted charge.

It is to be noted that the effects described in the present specification are merely exemplary and are not limited thereto, and may further include other effects. This similarly applies to effects of following other embodiments.

### 2. Practical Application Examples

The technology according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, a robot, a construction machine, or an agricultural machine (tractor).

FIG. 14 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 14, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 14 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

FIG. 15 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper, or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 15 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by super-imposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 14, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave.

On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing rainfall, fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random-access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handy-phone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the micro-computer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 14, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 14 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

In the vehicle control system 7000 described above, the imaging device of the present disclosure is applicable to the imaging section 7410 and the imaging sections 7910, 7912, 7914, 7916, and 7918.

### 3. Other Embodiments

The technology in the present disclosure is not limited to the above-described embodiment, and may be modified in a wide variety of ways.

For example, the present technology may also have the following configurations.

According to the present technology of the following configurations, a plurality of structures having a width smaller than a wavelength of light of an associated color filter are disposed corresponding to a first pixel section and a second pixel section in each of a plurality of unit pixels. As a result, it is possible to expand a dynamic range.
(1)

An imaging device including:
a plurality of unit pixels arranged two-dimensionally; and
a layer that focuses light toward the plurality of unit pixels, in which
each of the plurality of unit pixels includes a first pixel section having a first sensitivity and a second pixel section having a second sensitivity lower than the first sensitivity, and
the light-focusing layer includes
a material having a first refractive index, and
a plurality of structures provided in the material, each of the plurality of structures having a second refractive index higher than the first refractive index, each of the plurality of structures having a width smaller than a wavelength of light of an associated color filter, the plurality of structures being disposed corresponding to the first pixel section and the second pixel section.
(2)

The imaging device according to (1), in which an area of the second pixel section is smaller than an area of the first pixel section.
(3)

The imaging device according to (1) or (2), wherein the first pixel section has an area larger than an area of the second section.
(4)

The imaging device according to (1) to (3), in which
a planar shape of the first pixel section is an L-shape, and
a planar shape of the second pixel section is rectangular.
(5)

The imaging device according to any one of (1) to (4), in which the plurality of structures in the light-focusing layer are cylindrical.
(6)

The imaging device according to any one of (1) to (5), in which the plurality of structures in the light-focusing layer is configured to include a linear pattern in a planar shape.
(7)

The imaging device according to any one of (1) to (6), further including: a plurality of color filters that are arranged two-dimensionally corresponding to the plurality of unit pixels and that differ in color from each other, in which the plurality of structures are disposed corresponding to a color of the plurality of color filters.
(8)

The imaging device according to any one of (1) to (7), wherein the first pixel section and the second pixel section have a ring pattern.
(9)

The imaging device according to any one of (1) to (8),
wherein the first pixel section is octagonal, and
wherein the second pixel section is rectangular.
(10)

The imaging device according to any one of (1) to (9), further comprising:
a plurality of color filters arranged two-dimensionally corresponding to the plurality of unit pixels and that differ in color from each other, wherein a height of each of the plurality of structures depends on a color of the associated color filter.
(11)

The imaging device according to any one of (1) to (10), further comprising:
a plurality of color filters arranged two-dimensionally corresponding to the plurality of unit pixels and that differ in color from each other, wherein a diameter of each of the plurality of structures depends on a color of the associated color filter.
(12)

The imaging device according to any one of (1) to (11), further comprising:
a plurality of color filters arranged two-dimensionally corresponding to the plurality of unit pixels and that differ in color from each other, wherein a distance between adjacent structures of the plurality of structures depends on a color of the associated color filter.
(13)

The imaging device according to any one of (1) to (12), wherein the first pixel section and the second pixel section have a ring pattern.
(14)

An electronic apparatus comprising an imaging device
the imaging device including:
a plurality of unit pixels arranged two-dimensionally; and
a light-focusing layer that focuses light toward the plurality of unit pixels, wherein each of the plurality of unit pixels includes a first pixel section and a second pixel section; and
the light-focusing layer includes:
a material having a first refractive index, and
a plurality of structures provided in the material and disposed corresponding to the first pixel section and the second pixel section, wherein each of the plurality of structures has a second refractive index higher than the first refractive index, and wherein each of the plurality of structures has a width smaller than a wavelength of light of an associated color filter; and
a processing circuit that processes a generated image signal.
(15)

The electronic apparatus according to (14), wherein an area of the second pixel section is smaller than an area of the first pixel section.
(16)

The electronic apparatus according to (14) or (15), wherein the first pixel section has an area larger than an area of the second section.
(17)

The electronic apparatus according to any one of (14) to (16),
wherein a planar shape of the first pixel section is octagonal, and
wherein a planar shape of the second pixel section is rectangular.
(18)

The electronic apparatus according to any one of (14) to (17),
wherein the first pixel section is L-shaped, and
wherein the second pixel section is rectangular.
(19)

The electronic apparatus according to any one of (14) to (18), further comprising:
a plurality of color filters arranged two-dimensionally corresponding to the plurality of unit pixels and that differ in color from each other, wherein a fill factor of each of the plurality of structures depends on a color of the associated color filter.
(20)

The electronic apparatus according to any one of (14) to (19), further comprising:
a plurality of color filters arranged two-dimensionally corresponding to the plurality of unit pixels and that differ in color from each other, wherein a height of each of the plurality of structures depends on a color of the associated color filter.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

10 filter layer
11R R (red) filter
11G G (green) filter
11B B (blue) filter
12 light-blocking film
13 planarization film (spacer film)
20 light-receiving layer (semiconductor substrate)
21 light-receiving device (PD (photodiode))
22 pixel separating section
30 microlens
40 light-focusing layer
41 structure (high refractive index material)
42 medium (low refractive index material)
50 antireflection film
100R R (red) pixel (unit pixel)
100G G (green) pixel (unit pixel)
100B B (blue) pixel (unit pixels)
100H high sensitivity pixel (first pixel section)
100L low sensitivity pixel (second pixel section)
7410 imaging section
7910, 7912, 7914, 7916, 7918 imaging section
Pa, Pb, Pc, Pd, Pe point

What is claimed is:

1. An imaging device, comprising:
a plurality of unit pixels arranged two-dimensionally; and
a light-focusing layer that focuses light toward the plurality of unit pixels,
wherein each of the plurality of unit pixels includes a first pixel section and a second pixel section; and
the light-focusing layer includes:
a material having a first refractive index, and
a plurality of structures provided in the material and disposed corresponding to the first pixel section and the second pixel section, wherein each of the plurality of structures has a second refractive index higher than the first refractive index, and wherein each of the plurality of structures has a width smaller than a wavelength of light of an associated color filter.

2. The imaging device according to claim 1, wherein an area of the second pixel section is smaller than an area of the first pixel section.

3. The imaging device according to claim 1, wherein the first pixel section has an area larger than an area of the second section.

4. The imaging device according to claim 2, wherein the first pixel section is L-shaped, and wherein the second pixel section is rectangular.

5. The imaging device according to claim 1, wherein the plurality of structures in the light-focusing layer are cylindrical.

6. The imaging device according to claim 1, wherein the plurality of structures in the light-focusing layer are configured to include a linear pattern in a planar shape.

17. The imaging device according to claim 1, further comprising:
a plurality of color filters arranged two-dimensionally corresponding to the plurality of unit pixels and that differ in color from each other, wherein a fill factor of each of the plurality of structures depends on a color of the associated color filter.

18. The imaging device according to claim 4, wherein the first pixel section and the second pixel section have a ring pattern.

9. The imaging device according to claim 1,
wherein the first pixel section is octagonal, and
wherein the second pixel section is rectangular.

10. The imaging device according to claim 1, further comprising:
a plurality of color filters arranged two-dimensionally corresponding to the plurality of unit pixels and that differ in color from each other, wherein a height of each of the plurality of structures depends on a color of the associated color filter.

11. The imaging device according to claim 1, further comprising:
a plurality of color filters arranged two-dimensionally corresponding to the plurality of unit pixels and that differ in color from each other, wherein a diameter of each of the plurality of structures depends on a color of the associated color filter.

12. The imaging device according to claim 1, further comprising:
a plurality of color filters arranged two-dimensionally corresponding to the plurality of unit pixels and that differ in color from each other, wherein a distance between adjacent structures of the plurality of structures depends on a color of the associated color filter.

13. The imaging device according to claim 9, wherein the first pixel section and the second pixel section have a ring pattern.

14. An electronic apparatus comprising an imaging device,
the imaging device including:
a plurality of unit pixels arranged two-dimensionally; and
a light-focusing layer that focuses light toward the plurality of unit pixels, wherein each of the plurality of unit pixels includes a first pixel section and a second pixel section; and
the light-focusing layer includes:
a material having a first refractive index, and
a plurality of structures provided in the material and disposed corresponding to the first pixel section and the second pixel section, wherein each of the plurality of structures has a second refractive index higher than the first refractive index, and wherein each of the plurality of structures has a width smaller than a wavelength of light of an associated color filter; and
a processing circuit that processes a generated image signal.

15. The electronic apparatus according to claim 14, wherein an area of the second pixel section is smaller than an area of the first pixel section.

16. The electronic apparatus according to claim 14, wherein the first pixel section has an area larger than an area of the second section.

17. The electronic apparatus according to claim 14,
wherein a planar shape of the first pixel section is octagonal, and
wherein a planar shape of the second pixel section is rectangular.

18. The electronic apparatus according to claim 14,
wherein the first pixel section is L-shaped, and
wherein the second pixel section is rectangular.

19. The electronic apparatus according to claim 14, further comprising:
a plurality of color filters arranged two-dimensionally corresponding to the plurality of unit pixels and that differ in color from each other, wherein a fill factor of each of the plurality of structures depends on a color of the associated color filter.

20. The electronic apparatus according to claim 14, further comprising:
a plurality of color filters arranged two-dimensionally corresponding to the plurality of unit pixels and that differ in color from each other, wherein a height of each of the plurality of structures depends on a color of the associated color filter.
